(19) United States
(12) Patent Application Publication
(10) Pub. No.: US 2026/0133302 A1
(43) Pub. Date: May 14, 2026

(54) SYSTEM AND METHOD OF SYSTEM

(71) Applicant: CANON KABUSHIKI KAISHA, Tokyo (JP)

(72) Inventors: TAKESHI IDE, Kanagawa (JP); TADASHI EGUCHI, Tokyo (JP)

(21) Appl. No.: 19/371,708

(22) Filed: Oct. 28, 2025

(30) Foreign Application Priority Data
Nov. 8, 2024 (JP) 2024-195709

(51) Int. Cl. G01S 11/12; H03K 5/00; H03K 21/08

(52) U.S. Cl. CPC G01S 11/12; H03K 21/08; H03K 2005/00286

(57) ABSTRACT

A system includes a first coupler having one end portion terminated that receives a first signal input from another end portion, a second coupler that moves in a direction in which the first coupler extends while maintaining a certain distance from the first coupler, a transmission unit that receives a second signal having a frequency same as a frequency of the first signal and transmit a signal, a reception unit that receives the signal output from the transmission unit, a detection unit that detects a phase difference between a signal output from the second coupler via the first coupler based on the first signal and a signal output from the reception unit via the transmission unit based on the second signal, and a calculation unit that calculates a position based on information of the phase difference output from the detection unit.

### BACKGROUND

### Field of the Technology

The aspect of the embodiments relates to a system which measures the displacement of a detection device moving on a transmission line, and a method of the system.

### Description of the Related Art

In recent years, a system which measures a displacement of a detection device moving on a transmission line has been studied and developed. For example, a system which generates a standing wave on a transmission line and measures a displacement of a detection device on the transmission line by acquiring an amplitude level and a phase of the standing wave through the detection device is proposed in IEEE Sensors Journal, Volume 23, No. 16, 15 Aug. 2023, P. 18609-18623, “A Wide-Range Transmission Line-Based Linear Displacement Sensor”.

### SUMMARY

According to an aspect of the embodiments, a system includes a first coupler having one end portion terminated and configured to receive a first signal input from another end portion, a second coupler configured to move in a direction in which the first coupler extends while maintaining a certain distance from the first coupler, a transmission unit configured to receive a second signal having a frequency same as a frequency of the first signal and transmit a signal, a reception unit configured to receive the signal output from the transmission unit, a detection unit configured to detect a phase difference between a signal output from the second coupler via the first coupler based on the first signal and a signal output from the reception unit via the transmission unit based on the second signal, and a calculation unit configured to calculate a position based on information of the phase difference output from the detection unit.

Features of the disclosure will become apparent from the following description of embodiments with reference to the attached drawings. The following description of embodiments is described by way of example.

### BRIEF DESCRIPTION OF THE DRAWINGS

FIG. 1 is a diagram illustrating a configuration of a displacement measurement system according to a first embodiment.

FIG. 2 is a diagram illustrating a configuration of a phase difference detection unit according to the first embodiment.

FIG. 3 is a graph illustrating a relationship between a displacement and a phase difference of a transmission line coupler according to the first embodiment.

FIG. 4 is a diagram illustrating a configuration of a displacement measurement system according to a second embodiment.

FIG. 5 is a graph illustrating a relationship between a displacement and a phase difference of a transmission line coupler according to the second embodiment.

FIG. 6 is a diagram illustrating a configuration of a displacement measurement system according to a third embodiment.

FIG. 7A is a graph illustrating a data transmission/reception waveform with respect to time according to the third embodiment.

FIG. 7B is a graph illustrating a data transmission/reception waveform with respect to time according to the third embodiment.

FIG. 7C is a graph illustrating a data transmission/reception waveform with respect to time according to the third embodiment.

FIG. 8 is a diagram illustrating configuration of a displacement measurement system according to a fourth embodiment.

FIG. 9A is a graph illustrating a relationship between a displacement and a phase difference of a transmission line coupler according to the fourth embodiment.

FIG. 9B is a graph illustrating a relationship between a displacement and a phase difference of a transmission line coupler according to the fourth embodiment.

FIG. 10A is a diagram illustrating a configuration of a displacement measurement system according to a fifth embodiment.

FIG. 10B is a diagram illustrating a configuration of a displacement measurement system according to the fifth embodiment.

FIG. 10C is a diagram illustrating a configuration of a displacement measurement system according to the fifth embodiment.

FIG. 11A is a graph illustrating a relationship between a displacement and a phase difference of a transmission line coupler according to the fifth embodiment.

FIG. 11B is a graph illustrating a relationship between a displacement and a phase difference of a transmission line coupler according to the fifth embodiment.

FIG. 12 is a diagram illustrating a configuration of a displacement measurement system according to a sixth embodiment.

### DESCRIPTION OF THE EMBODIMENTS

Embodiments of the disclosure will be described below with reference to the drawings.

### First Embodiment

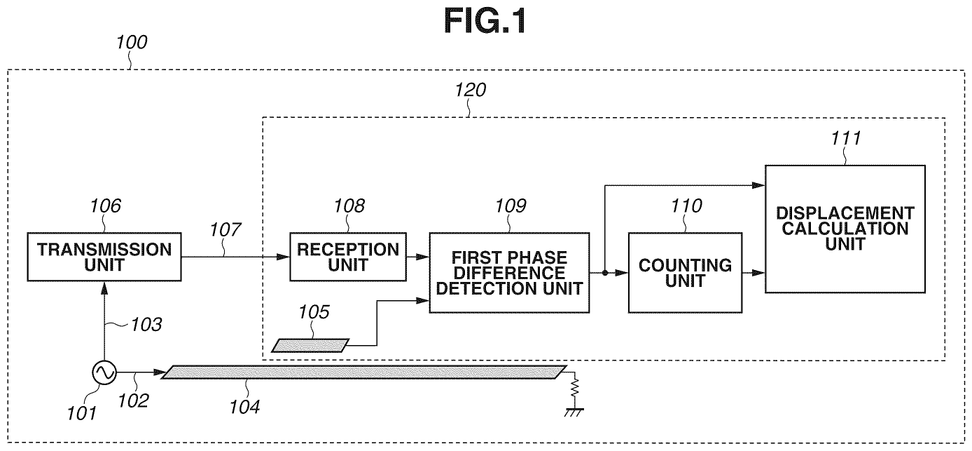

FIG. 1 is a diagram illustrating a configuration of a displacement measurement system according to the embodiment. A displacement measurement system 100 includes a first alternating current signal source 101, a first cable 102, a second cable 103, a first transmission line coupler 104, a first coupler 105, a transmission unit 106, a propagation path 107, a reception unit 108, a first phase difference detection unit 109, a counting unit 110, and a displacement calculation unit 111.

The first coupler 105, the reception unit 108, the first phase difference detection unit 109, the counting unit 110, and the displacement calculation unit 111 integrally move in a direction where the first transmission line coupler 104 extends, i.e., a signal transmission direction, by receiving power from a motor (not illustrated in FIG. 1).

The first alternating current signal source 101 outputs a sine-wave signal of an arbitrary frequency. The first transmission line coupler 104 is a linear transmission line. A first signal from the first alternating current signal source 101 is input to one end portion of the first transmission line coupler 104 via the first cable 102, and the other end portion thereof is terminated with a resistor having an impedance equivalent to the characteristic impedance of the transmission line. The first transmission line coupler 104 includes a ground (GND) (not illustrated) as an element which determines the characteristic impedance of the transmission line. A transmission line coupler described below similarly includes a GND (not illustrated). The first coupler 105 is a linear transmission line shorter than the first transmission line coupler 104. The first coupler 105 moves while maintaining a certain distance from the first transmission line coupler 104. The moving direction of the first coupler 105 is parallel to the signal transmission direction of the first transmission line coupler 104, and is either in the forward direction or in the reverse direction with respect to the signal transmission direction. The first coupler 105 is not terminated at both end portions of the transmission line, but may alternatively be a transmission line coupler that is terminated with matching impedance. The first coupler 105 is electromagnetically coupled to the first transmission line coupler 104, and a signal input to the first transmission line coupler 104 is received by the first coupler 105 via electromagnetic coupling. For example, the first transmission line coupler 104 is a transmission line including a printed circuit board on which a signal line and a GND are arranged.

The transmission unit 106 transmits a signal from the first alternating current signal source 101, which is input via the second cable 103, to the propagation path 107. The signal transmitted from the transmission unit 106 passes through the propagation path 107 and is received by the reception unit 108. In the embodiment, it is assumed that the transmission unit 106 includes a light emitting element, the reception unit 108 includes a light receiving element, and the propagation path 107 is air. The light emitting element and the light receiving element are optically coupled to each other, so that the signal transmitted from the transmission unit 106 is received by the reception unit 108. Light whose intensity varies depending on the frequency of the first alternating current signal source 101 propagates through the air serving as the propagation path 107.

The first phase difference detection unit 109 detects and outputs a phase difference between the signals received respectively by the first coupler 105 and the reception unit 108. The counting unit 110 counts the number of times the phase difference output from the first phase difference detection unit 109 becomes equal to or greater than 180 degrees or equal to or less than −180 degrees, and changes the value stored in the counter. The counting unit 110 may increment the value when the phase difference becomes equal to or greater than 180 degrees, and may decrement the value when the phase difference becomes equal to or less than −180 degrees. Alternatively, a first counted value may be incremented when the phase difference becomes equal to or greater than 180 degrees, and a second counted value may be incremented when the phase difference becomes equal to or less than −180 degrees. In this manner, the calculation may be executed by using the first and second counted values.

A moving unit 120 includes the first coupler 105, the reception unit 108, the first phase difference detection unit 109, the counting unit 110, and the displacement calculation unit 111. The moving unit 120 moves integrally in a direction the first transmission line coupler 104 extends, i.e., a signal transmission direction or a direction opposite to the signal transmission direction, by receiving power from a motor (not illustrated in FIG. 1) or the like. The displacement measurement system 100 of the embodiment is intended to measure this moving distance as a displacement.

As described above, the moving unit 120 moves in a horizontal direction while maintaining a certain distance from the first transmission line coupler 104. Along with the movement of the moving unit 120, the first coupler 105, which receives a signal from the first transmission line coupler 104, and the reception unit 108, which receives a signal from the transmission unit 106, similarly move in the horizontal direction. Since the positions of the first coupler 105 and the reception unit 108 are fixed within the same moving unit 120, the first coupler 105 and the reception unit 108 always change by the same distance. In other words, assuming a position where the first coupler 105 and the reception unit 108 are located is an initial position, the respective moving distances of the first coupler 105 and the reception unit 108 from the initial position to the position after movement are the same as a result of the horizontal movement.

A method for measuring a displacement by detecting a phase difference is described. The amount of phase change, which occurs when a signal propagates from the first alternating current signal source 101 to the first phase difference detection unit 109 via the first cable 102, the first transmission line coupler 104, and the first coupler 105, in a state where the moving unit 120 is located at the initial position, is denoted by φ₁. The amount of phase change, which occurs when a signal propagates from the first alternating current signal source 101 to the first phase difference detection unit 109 via the second cable 103, the transmission unit 106, the propagation path 107, and the reception unit 108, in a state where the moving unit 120 is located at the initial position, is denoted by φ₂.

The frequency of the signal output from the first alternating current signal source 101 is denoted by f, the propagation speed when the signal from the first alternating current signal source 101 propagates through the first transmission line coupler 104 is denoted by v₁, and the propagation speed when the signal propagates through the propagation path 107 is denoted by v₂.

The amount of phase change θ₁, which occurs when a signal propagates from the first alternating current signal source 101 to the first phase difference detection unit 109 via the first cable 102, the first transmission line coupler 104, and the first coupler 105, in a state where the moving unit 120 is displaced from the initial position by a distance L, is expressed by the following equation.

$${θ}_{1} = 2 π f \frac{L}{{v}_{1}} + {φ}_{1} \qquad ( Equation 1 )$$

Similarly, the amount of phase change θ₂, which occurs when a signal propagates from the first alternating current signal source 101 to the first phase difference detection unit 109 via the second cable 103, the transmission unit 106, the propagation path 107, and the reception unit 108, is expressed by the following equation.

$${θ}_{2} = 2 π f \frac{L}{{v}_{2}} + {φ}_{2} \qquad ( Equation 2 )$$

In a state where the moving unit 120 is displaced from the initial position by a distance L, a phase difference Δθ detected by the first phase difference detection unit 109 is calculated as a difference between the above-described equations 1 and 2 and expressed by the following equation.

$$Δθ = {θ}_{2} - {θ}_{1} = 2 π f ( \frac{L}{{v}_{2}} - \frac{L}{{v}_{1}} ) + ( {φ}_{2} - {φ}_{1} ) \qquad ( Equation 3 )$$

When the equation 3 is organized in terms of the distance L from the initial position, the distance L is expressed by the following equation.

$$L = \{ Δθ - ( {φ}_{2} - {φ}_{1} ) \} / \{ 2 π f ( \frac{1}{{v}_{2}} - \frac{1}{{v}_{1}} ) \} \qquad ( Equation 4 )$$

If there is a difference between the propagation speed v₁ of the first transmission line coupler 104 and the propagation speed v₂ of the propagation path 107, a displacement can be measured by detecting a phase difference because the distance L can be calculated from the phase difference Δθ detected by the first phase difference detection unit 109.

The counting unit 110 sets the initial value of the internal counter to 0, and treats the value output from the first phase difference detection unit 109 when the moving unit 120 is located at the initial position as an initial phase difference. In a case where the phase difference output from the first phase difference detection unit 109, in connection with the movement of the moving unit 120, exceeds 180 degrees, the counting unit 110 increments the internal counter by 1, and outputs a value acquired by subtracting 360 degrees, i.e., −180 degrees. Similarly, in a case where the phase difference becomes less than −180 degrees, the counting unit 110 decrements the internal counter by 1, and outputs a value acquired by adding 360 degrees, i.e., 180 degrees. Therefore, a phase difference Δθ can be calculated from the values output from the counting unit 110 and the first phase difference detection unit 109. In the equation 4, the initial phases φ₁ and φ₂, the frequency f, the propagation speeds v₁ and v₂ of the signals propagated through the respective transmission paths are all known values. Therefore, a displacement can be calculated from the phase difference Δθ with the displacement calculation unit 111.

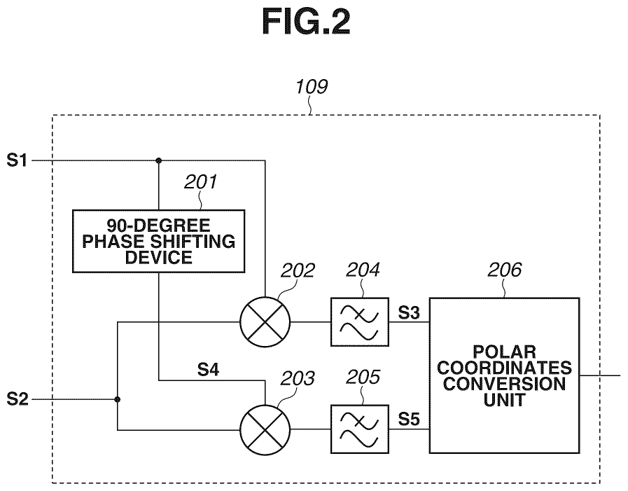

FIG. 2 illustrates an example of the configuration of the first phase difference detection unit 109 according to the embodiment. The first phase difference detection unit 109 includes a 90-degree phase shifting device 201, multiplication devices 202 and 203, low-pass filters 204 and 205, and a polar coordinates conversion unit 206.

The 90-degree phase shifting device 201, the multiplication devices 202 and 203, and the low-pass filters 204 and 205 may be collectively called “orthogonal demodulation unit”.

A signal S₀ output from the first alternating current signal source 101 is expressed by the following equation.

$${S}_{0} = {A}_{0} sin ( 2 π f t + {θ}_{0} ) \qquad ( Equation 5 )$$

the amplitude of the signal S₀ of the first alternating current signal source 101 is denoted by A₀, time is denoted by t, and the initial phase of the signal S₀ of the first alternating current signal source 101 when time t is 0 (i.e., t=0) is denoted by θ₀. When the signal that propagates from the first alternating current signal source 101 to the first phase difference detection unit 109 via the first cable 102, the first transmission line coupler 104, and the first coupler 105 at a position L of the moving unit 120 is S₁, the signal S₁ is expressed by the following equation.

$${S}_{1} = {A}_{0} {A}_{1} sin ( 2 π f t + {θ}_{0} - {θ}_{1} ) \qquad ( Equation 6 )$$

A₁ represents the rate of amplitude change caused by the propagation of the signal from the first alternating current signal source 101 to the first phase difference detection unit 109 via the first cable 102, the first transmission line coupler 104, and the first coupler 105. When the signal that propagates from the first alternating current signal source 101 to the first phase difference detection unit 109 via the second cable 103, the transmission unit 106, the propagation path 107, and the reception unit 108 at the position L of the moving unit 120 is S₂, the signal S₂ is expressed by the following equation.

$${S}_{2} = {A}_{0} {A}_{2} sin ( 2 π f t + {θ}_{0} - {θ}_{2} ) \qquad ( Equation 7 )$$

A₀ represents the rate of amplitude change caused by the propagation of the signal from the first alternating current signal source 101 to the first phase difference detection unit 109 via the second cable 103, the transmission unit 106, the propagation path 107, and the reception unit 108. The multiplication device 202 multiplies the signals S₁ and S₂, and the multiplication result is expressed by the following equation.

$$\begin{matrix}{S}_{1} \cdot {S}_{2} = {A}_{0}^{2} {A}_{1} {A}_{2} sin ( 2 π f t + {θ}_{0} - {θ}_{1} ) \cdot sin ( 2 π f t + {θ}_{0} - {θ}_{2} ) \\ = \frac{1}{2} {A}_{0}^{2} {A}_{1} {A}_{2} \{ cos ( {θ}_{2} - {θ}_{1} ) - cos ( 4 π f t + 2 {θ}_{0} - {θ}_{1} - {θ}_{2} ) \}\end{matrix} \qquad ( Equation 8 )$$

When the output of the multiplication device 202 is input to the low-pass filter 204, in one embodiment, only the low-order harmonic component, expressed by the first term of the equation 8, passes through the low-pass filter 204, so that a signal S₃ expressed by the following equation 9 is acquired.

$${S}_{3} = \frac{1}{2} {A}_{0}^{2} {A}_{1} {A}_{2} cos ( {θ}_{2} - {θ}_{1} ) = \frac{1}{2} {A}_{0}^{2} {A}_{1} {A}_{2} cos ( 2 π f ( \frac{L}{{v}_{2}} - \frac{L}{{v}_{1}} ) + ( {φ}_{2} - {φ}_{1} ) ) \qquad ( Equation 9 )$$

The 90-degree phase shifting device 201 delays the phase of the signal S₁ by 90 degrees, and a signal S₄ acquired as a result of the delay is expressed by the following equation 10.

$${S}_{4} = {A}_{0} {A}_{1} sin ( 2 π f t + {θ}_{0} - {θ}_{1} - \frac{π}{2} ) = - {A}_{0} {A}_{1} cos ( 2 π f t + {θ}_{0} - {θ}_{1} ) \qquad ( Equation 10 )$$

The multiplication device 203 multiplies the signals S₂ and S₄, and the multiplication result is expressed by the following equation.

$$\begin{matrix}{S}_{2} \cdot {S}_{4} = - {A}_{0}^{2} {A}_{1} {A}_{2} cos ( 2 π f t + {θ}_{0} - {θ}_{1} ) \cdot sin ( 2 π f t + {θ}_{0} - {θ}_{2} ) \\ = - \frac{1}{2} {A}_{0}^{2} {A}_{1} {A}_{2} \{ sin ( 4 π f t + 2 {θ}_{2} - {θ}_{1} - {θ}_{2} ) - sin ( {θ}_{2} - {θ}_{1} ) \}\end{matrix} \qquad ( Equation 11 )$$

When the output of the multiplication device 203 is input to the low-pass filter 205, in one embodiment, only the low-order harmonic component, expressed by the second term of the equation 11, passes through the low-pass filter 205, so that a signal S₅ expressed by the following equation 12 is acquired.

$${S}_{5} = \frac{1}{2} {A}_{0}^{2} {A}_{1} {A}_{2} sin ( {θ}_{2} - {θ}_{1} ) = \frac{1}{2} {A}_{0}^{2} {A}_{1} {A}_{2} sin ( 2 π f ( \frac{L}{{v}_{2}} - \frac{L}{{v}_{1}} ) + ( {φ}_{2} - {φ}_{1} ) ) \qquad ( Equation 12 )$$

The polar coordinates conversion unit 206 converts the orthogonal coordinates acquired by the orthogonal demodulation unit using the equations 9 and 12 into polar coordinates, and outputs a phase difference expressed by the equation 3.

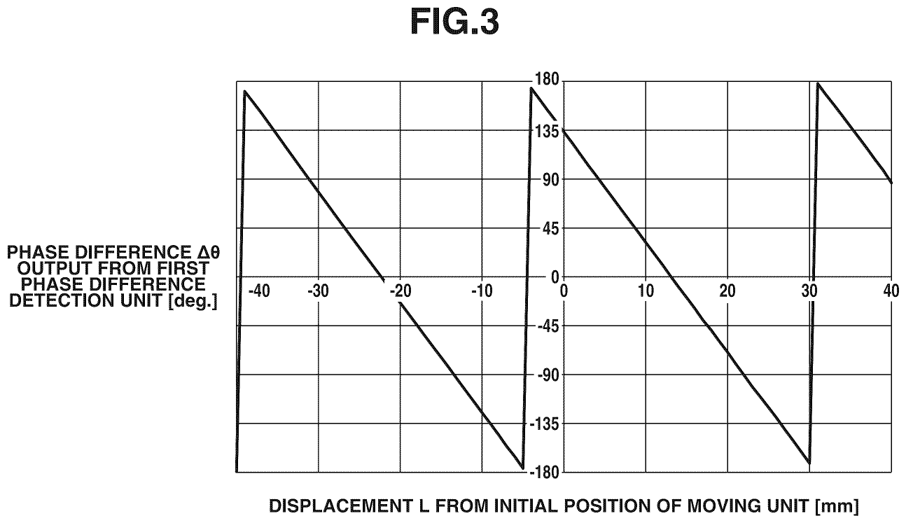

FIG. 3 illustrates a relationship between the displacement L of the moving unit 120 and the phase difference Δθ according to the embodiment. The horizontal axis represents a displacement L relative to the initial position L=0 mm of the moving unit 120, and the vertical axis represents the phase difference Δθ output from the first phase difference detection unit 109. The frequency f of the signal output from the first alternating current signal source 101 is set to 10 GHz, and the phase difference φ₂−φ₁ at the initial position L=0 mm is set to 133.2 degrees. The first transmission line coupler 104 is made of a glass epoxy substrate (FR4), and the propagation speed v₁ of the signal from the first alternating current signal source 101 that propagates through the first transmission line coupler 104 is set to 1.62×10⁸ m/s. The propagation path 107 is a path through which light output from the light emitting element of the transmission unit 106 is input to the reception unit 108, and the propagation speed v₂ of the signal from the first alternating current signal source 101 that propagates through the propagation path 107 is set to 3.00×10⁸ m/s.

Since the propagation speeds are different between the case where the signal of the first alternating current signal source 101 propagates through the first transmission line coupler 104 and the case where the signal propagates through the propagation path 107, the phase difference Δθ changes depending on the displacement L, as expressed by the equation 3, which is illustrated in FIG. 3. Accordingly, the displacement L of the moving unit 120 can be acquired by measuring the phase difference Δθ with the first phase difference detection unit 109.

For example, there are two positions of the coupler where the phase difference is indicated as 0, located near −22 mm and 13 mm. For example, in a case where the output value of the counting unit 110 is incremented by 1 every time the phase difference exceeds 180 degrees and decremented by 1 every time the phase difference falls below −180 degrees, 0 is output when the displacement L is 13 mm, and −1 is output when the displacement L is −22 mm. Accordingly, it is possible to identify the position of the first coupler 105 based on the output value of the counting unit 110 even if the phase difference is the same.

In the embodiment, a case in which the transmission unit 106, the propagation path 107, and the reception unit 108 are configured for optical propagation has been described. However, any other configuration may be used as long as the propagation time of the signal from the first alternating current signal source 101 through the propagation path 107 is different from the propagation time of the signal through the first transmission line coupler 104. For example, a radio wave, a sound wave, or the other technique may be used. Further, a cable, a fiber, a waveguide, a transmission line coupler made of a different base material, a slip ring, or other components may be used. Similarly, a cable, a fiber, a waveguide, a slip ring, or other components may also be used for the first transmission line coupler 104 and the first coupler 105 as long as the propagation time is different from the propagation time in the propagation path 107.

As described above, the displacement measurement system of the embodiment can maintain constant detection accuracy at any position on the transmission line without using amplitude levels.

### Second Embodiment

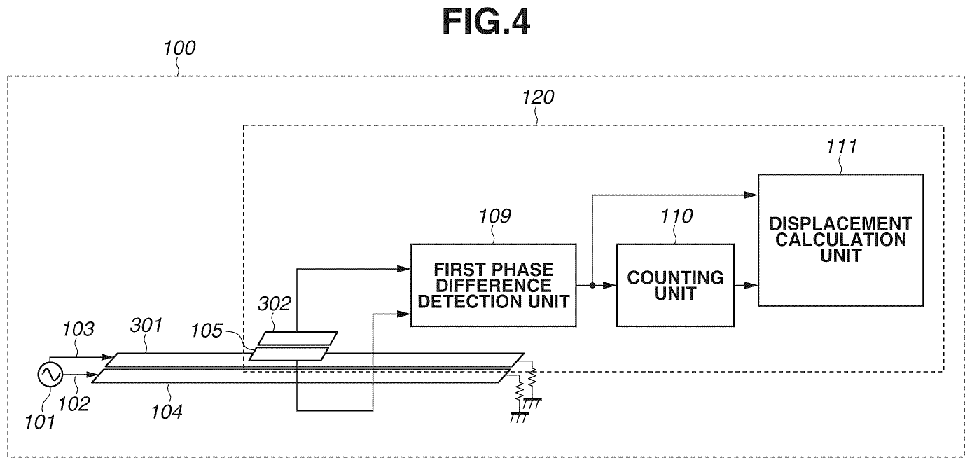

FIG. 4 illustrates a configuration of the displacement measurement system according to the embodiment, which includes a second transmission line coupler 301 and a second coupler 302 instead of the propagation path 107 described in the first embodiment. The displacement measurement system 100 includes the first alternating current signal source 101, the first cable 102, the second cable 103, the first transmission line coupler 104, the first coupler 105, the second transmission line coupler 301, the second coupler 302, the first phase difference detection unit 109, the counting unit 110, and the displacement calculation unit 111. The embodiment is described with respect to the configuration different from the first embodiment.

The second transmission line coupler 301 is a linear transmission line. A signal of the first alternating current signal source 101 is input to one end portion of the second transmission line coupler 301 via the second cable 103, and the other end portion thereof is terminated with a resistor having an impedance equivalent to the characteristic impedance of the transmission line. The second coupler 302 is a linear transmission line shorter than the second transmission line coupler 301. The second coupler 302 moves in a horizontal direction while maintaining a certain distance from the second transmission line coupler 301. Although both end portions of the transmission line of the second coupler 302 are not terminated, a transmission line coupler with matched termination may also be used. The second coupler 302 is electromagnetically coupled to the second transmission line coupler 301, and a signal input to the second transmission line coupler 301 is received by the second coupler 302 through the electromagnetic coupling. For example, the second transmission line coupler 301 is a transmission line including a printed circuit board on which a signal line and a GND are arranged. Similar to the first coupler 105, the second coupler 302 moves in a horizontal direction while maintaining a certain distance from the second transmission line coupler 301. Through the above movement, the position of the second coupler 302 which receives a signal from the second transmission line coupler 301 changes. Through the movement in the horizontal direction, the positions of the first coupler 105 and the second coupler 302 always change by the same distance. In other words, when the position where the moving distance of both the first coupler 105 and the second coupler 302 is 0 is assumed as the initial position, the respective moving distances of the first coupler 105 and the second coupler 302 from the initial position to the position after movement are the same as a result of the horizontal movement.

A method for measuring a displacement by detecting a phase difference according to the embodiment is described. The amount of phase change, which occurs when a signal propagates from the first alternating current signal source 101 to the first phase difference detection unit 109 via the first cable 102, the first transmission line coupler 104, and the first coupler 105, in a state where the moving unit 120 is located at the initial position, is denoted by φ₁. The amount of phase change, which occurs when a signal propagates from the first alternating current signal source 101 to the first phase difference detection unit 109 via the second cable 103, the second transmission line coupler 301, and the second coupler 302, in a state where the moving unit 120 is located at the initial position, is denoted by φ₂. Similar to the first embodiment, a phase difference Δθ is expressed by the equation 3.

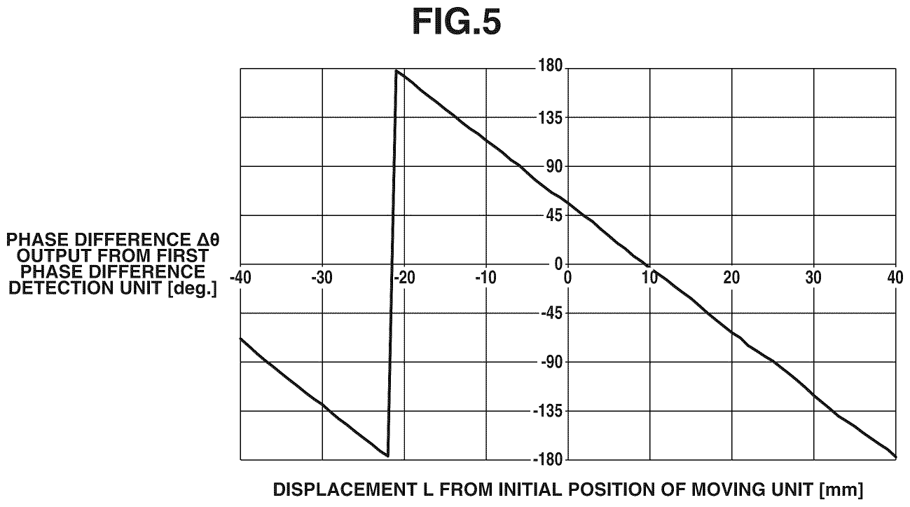

FIG. 5 illustrates a relationship between the displacement L of the moving unit 120 and the phase difference Δθ according to the embodiment. The horizontal axis represents the displacement L from the initial position L=0 mm of the moving unit 120, and the vertical axis represents the phase difference Δθ output from the first phase difference detection unit 109. The frequency f of the signal output from the first alternating current signal source 101 is set to 10 GHz, and the phase difference φ₂−φ₁ at the initial position L=0 mm is set to 56.8 degrees. The first transmission line coupler 104 is made of a glass epoxy substrate (FR4), whereas the second transmission line coupler 301 is made of a fluororesin substrate (Teflon®). The propagation speed v₁ when the signal from the first alternating current signal source 101 propagates through the second transmission line coupler 301 is set to 2.22×10⁸ m/s. The propagation speeds are different from each other because of a difference between the dielectric constant of glass epoxy and the dielectric constant of fluororesin. The glass epoxy and the fluororesin are merely examples, and any resin members may be used as long as the members have different dielectric constants or relative permittivity.

Since the propagation speeds are different between the case where a signal from the first alternating current signal source 101 propagates through the first transmission line coupler 104 and the case where the signal propagates through the propagation path 107, as illustrated in FIG. 5, the phase difference Δθ changes depending on the displacement L as expressed by the equation 3. Accordingly, the displacement L of the moving unit 120 can be acquired by measuring the phase difference Δθ with the first phase difference detection unit 109.

For example, although there are two positions of the coupler where the phase difference is indicated as −90 degrees, located near −37 mm and 25 mm, the values output from the counting unit 110 are different. Accordingly, it is possible to identify the position of the first coupler 105 based on the output value of the counting unit 110 even if the phase difference is the same.

As described above, according to the embodiment, the position of the first coupler 105 relative to the first transmission line coupler 104 can be calculated by the displacement calculation unit 111 based on the values output from the first phase difference detection unit 109 and the counting unit 110.

### Third Embodiment

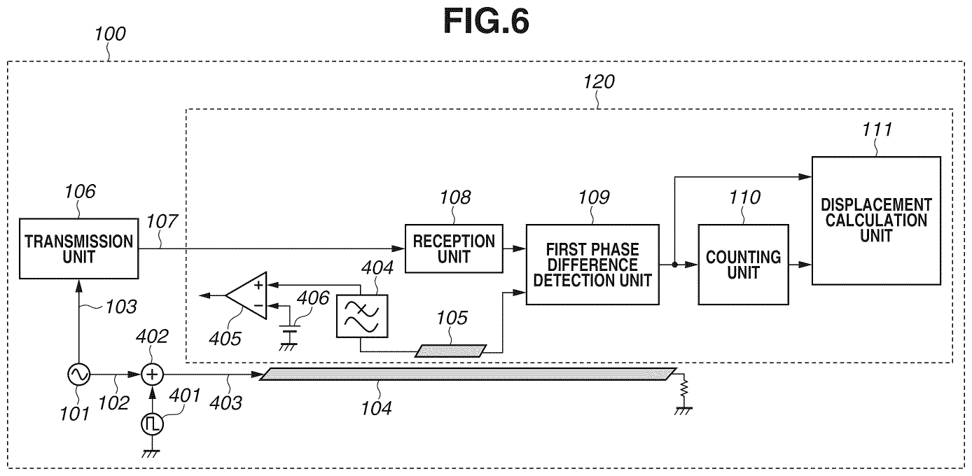

FIG. 6 is a diagram illustrating a configuration of a displacement measurement system according to the embodiment. FIG. 6 illustrates a configuration for simultaneously implementing data transmission and measurement of a displacement. The displacement measurement system 100 includes a data signal source 401, an addition device 402, a third cable 403, a low pass filter 404, a comparison device 405, and a constant voltage source 406, in addition to the components of the system described in the first embodiment. The data signal source 401 represents an optional digital data signal to be transmitted. The addition device 402 adds a signal from the first alternating current signal source 101 and an optional digital data signal represented by the data signal source 401, and outputs the resulting signal.

A method for measuring a displacement by detecting a phase difference according to the embodiment is described. The amount of phase change, which occurs when a signal propagates from the first alternating current signal source 101 to the first phase difference detection unit 109, in a state where the moving unit 120 is located at the initial position, is denoted by φ₁. This signal propagates via the first cable 102, the addition device 402, the third cable 403, the first transmission line coupler 104, and the first coupler 105. The amount of phase change, which occurs when a signal propagates from the first alternating current signal source 101 to the first phase difference detection unit 109 via the second cable 103, the transmission unit 106, the propagation path 107, and the reception unit 108, in a state where the moving unit 120 is located at the initial position, is denoted by φ₂. Similar to the first embodiment, the phase difference Δθ is expressed by the equation 3. A relationship between the displacement L of the moving unit 120 and the phase difference Δθ according to the embodiment is also illustrated in FIG. 3 as in the first embodiment.

Data transmission will be described. The displacement measurement system according to the embodiment can transmit an optional digital data signal represented by the data signal source 401 to the moving unit 120 through non-contact transmission, in addition to measuring the displacement L of the moving unit 120. Similar to the signal of the first alternating current signal source 101, the digital data signal added to the signal of the first alternating current signal source 101 is input to the first transmission line coupler 104, and is received by the first coupler 105 via the electromagnetic coupling. In a case where the digital data signal is sufficiently slower than the frequency f of the signal of the first alternating current signal source 101, the digital data signal and the signal of the first alternating current signal source 101 are separated by the low pass filter 404. In other words, the signal of the first alternating current signal source 101 is cut off by the low pass filter 404, and, in one embodiment, only the digital data signal is input to the comparison device 405.

The comparison device 405 outputs a signal corresponding to a logic value “1” in a case where the signal input to the comparison device 405 after passing the low-pass filter 404 is higher than a voltage level output by the constant voltage source 406, and outputs a signal corresponding to a logic value “0” in a case where the signal is lower than the voltage level output by the constant voltage source 406. The comparison device 405 shapes a waveform of the signal received by the first coupler 105 via the electromagnetic coupling and reproduces the original digital data signal represented by the data signal source 401. The reproduction method of the digital data signal is not limited to using the comparison device, and the waveform may alternatively be shaped by other methods.

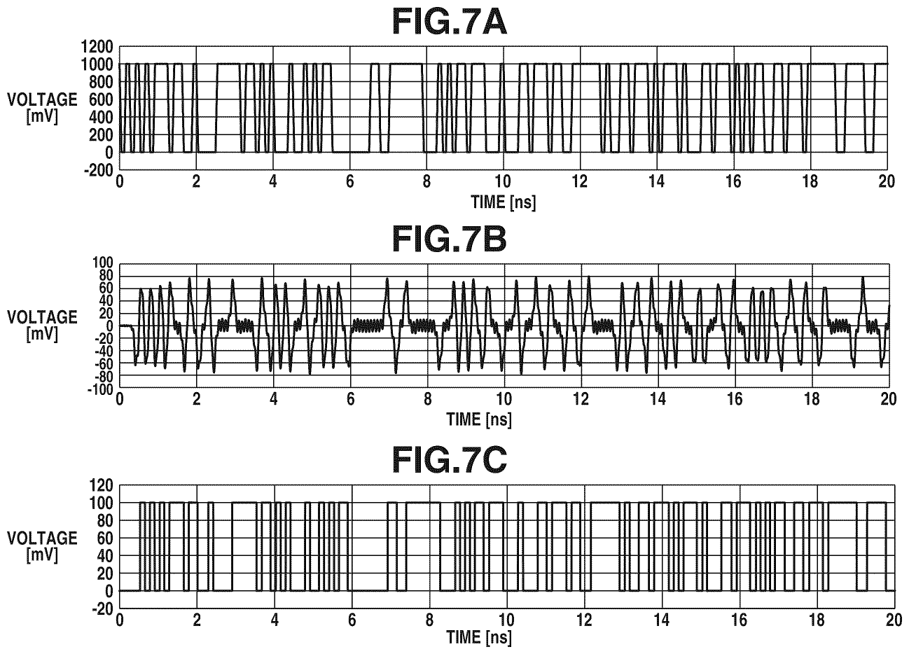

FIGS. 7A, 7B, and 7C each illustrate a relationship of data transmission and reception waveforms with respect to time. More specifically, in FIG. 7A, the horizontal axis represents time, and the vertical axis represents the output voltage of the data signal source 401. In FIG. 7B, the horizontal axis represents time, and the vertical axis represents the output voltage of the low pass filter 404. In FIG. 7C, the horizontal axis represents time, and the vertical axis represents the output voltage of the comparison device 405. The digital data signal of the data signal source 401 is a rectangular wave. This digital data signal is shaped into a differentiated waveform when the signal is transmitted to the first coupler 105 via electromagnetic field coupling, and is restored to a rectangular wave by the comparison device 405. As described above, by transmitting a signal to the first coupler 105 after adding the signal of the first alternating current signal source 101 and the digital data signal of the data signal source 401, the digital data signal can be transmitted to the moving unit 120 while acquiring the displacement L of the moving unit 120.

In the embodiment, a low-pas filter is used to separate the signal of the first alternating current signal source 101 and the digital data signal of the data signal source 401. However, the embodiment is not limited to the above. For example, a high-pass filter may be used in a case where the frequency of the signal of the first alternating current signal source 101 is lower than that of the digital data signal.

As described above, according to the embodiment, the position of the first coupler 105 relative to the first transmission line coupler 104 can be calculated by the displacement calculation unit 111 based on the values output from the first phase difference detection unit 109 and the counting unit 110. Further, the digital data signal of the data signal source 401 can be output from the comparison device 405 disposed in the moving unit 120. In other words, data can be transmitted to the moving unit 120 through non-contact transmission while detecting the position of the moving unit 120. Therefore, wear or disconnection of cables caused by movement of the cables is less likely to occur than in the case where data is transmitted using cable connections. Further, since the positional information of the first coupler 105 is acquired at the same time, it is possible to add control to vary the amplification level of a signal amplifier according to the position, for example when the signal-to-noise ratio of data transmission changes depending on the position.

### Fourth Embodiment

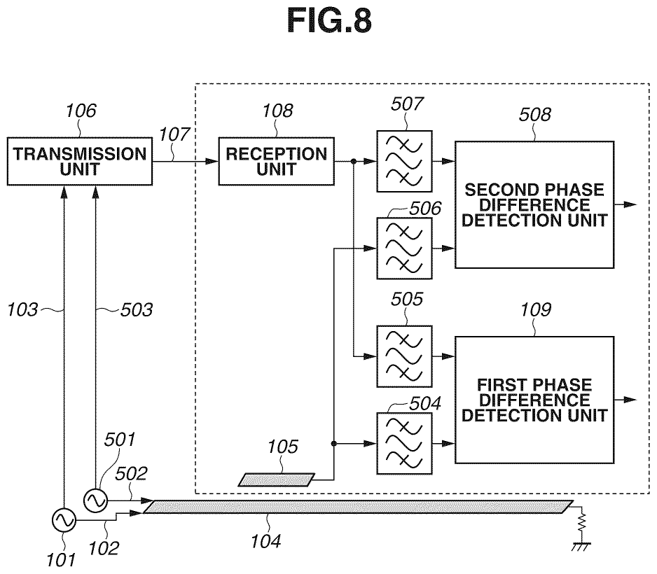

FIG. 8 is a diagram illustrating a configuration of a displacement measurement system according to the embodiment. The displacement measurement system according to the embodiment includes a second alternating current signal source 501, a fourth cable 502, a fifth cable 503, a band-pass filters 504, 505, 506, and 507, and a second phase difference detection unit 508, in addition to the components of the system described in the first embodiment. The counting unit 110 is not included because it is not used in the embodiment. The second alternating current signal source 501 generates a sine-wave signal having a frequency different from the frequency of the signal output from the first alternating current signal source 101.

The signal from the first alternating current signal source 101 and the signal from the second alternating current signal source 501 are input to the first transmission line coupler 104 via the first cable 102 and the fourth cable 502, respectively. The two signals having different frequencies from each other, which are input to the first transmission line coupler 104, are transmitted to the first coupler 105 via electromagnetic coupling, and then input to the band-pass filters 504 and 506. The band-pass filters 504 and 506 have different passband frequencies, allowing the frequencies of the signals from the first alternating current signal source 101 and the second alternating current signal source 501 to pass, respectively. In other words, the signal from the first alternating current signal source 101 is input to the first phase difference detection unit 109, and the signal from the second alternating current signal source 501 is input to the second phase difference detection unit 508.

A signal from the first alternating current signal source 101 and a signal from the second alternating current signal source 501 are input to the transmission unit 106 via the second cable 103 and the fifth cable 503, respectively. The two signals having different frequencies from each other, input to the transmission unit 106, are transmitted to the reception unit 108 via optical propagation through the propagation path 107, and then are input to the band-pass filters 505 and 507. The band-pass filters 505 and 507 have different passband frequencies, allowing the frequencies of the signals from the first alternating current signal source 101 and the second alternating current signal source 501 to pass, respectively. In other words, a signal from the first alternating current signal source 101 is input to the first phase difference detection unit 109, and a signal from the second alternating current signal source 501 is input to the second phase difference detection unit 508.

Therefore, the first phase difference detection unit 109 detects a phase difference between the signal that has propagated from the first alternating current signal source 101 via the first transmission line coupler 104 and the signal that has propagated from the first alternating current signal source 101 via the propagation path 107. The second phase difference detection unit 508 detects a phase difference between the signal that has propagated from the second alternating current signal source 501 via the first transmission line coupler 104 and the signal that has propagated from the second alternating current signal source 501 via the propagation path 107. The propagation path through which the signal propagates from the first alternating current signal source 101 to the first phase difference detection unit 109 is the same as the propagation path through which the signal propagates from the second alternating current signal source 501 to the second phase difference detection unit 508. However, since the frequency of the first alternating current signal source 101 and the frequency of the second alternating current signal source 501 are different, the phase difference detected by the first phase difference detection unit 109 is different from the phase difference detected by the second phase difference detection unit 508, and the first phase difference detection unit 109 and the second phase difference detection unit 508 each detects an individual phase difference with respect to the position of the moving unit 120.

The position of the moving unit 120 is calculated from the information about the two phase differences acquired by the first and second phase difference detection units 109 and 508. In this way, it is possible to detect the position of the moving unit 120 without using the internal counter information of the counting unit 110.

A method for measuring a displacement by detecting a phase difference according to the embodiment is described. The amount of phase change, which occurs when a signal propagates from the first alternating current signal source 101 to the first phase difference detection unit 109, in a state where the moving unit 120 is located at the initial position, is denoted by φ₁. This signal propagates via the first cable 102, the first transmission line coupler 104, the first coupler 105, and the band-pass filter 504. The amount of phase change, which occurs when a signal propagates from the first alternating current signal source 101 to the first phase difference detection unit 109, in a state where the moving unit 120 is located at the initial position, is denoted by φ₂. This signal propagates via the second cable 103, the transmission unit 106, the propagation path 107, the reception unit 108, and the band-pass filter 505. Similar to the first embodiment, a phase difference Δθ is expressed by the equation 3. A relationship between the displacement L of the moving unit 120 and the phase difference Δθ according to the embodiment is also illustrated in FIG. 3 as in the first embodiment.

Similarly, the amount of phase change, which occurs when a signal propagates from the second alternating current signal source 501 to the second phase difference detection unit 508, via the fourth cable 502, the first transmission line coupler 104, the first coupler 105, and the band-pass filter 506, is denoted by φ₁′. The amount of phase change, which occurs when a signal propagates from the second alternating current signal source 501 to the second phase difference detection unit 508, in a state where the moving unit 120 is located at the initial position, is denoted by φ₂′. This signal propagates via the fifth cable 503, the transmission unit 106, the propagation path 107, the reception unit 108, and the band-pass filter 507. When the frequency of the second alternating current signal source 501 is f′, and the phase difference detected by the second phase difference detection unit 508 is Δθ′, the phase difference Δθ′ is expressed by the following equation, similar to the equation 3 described in the first embodiment.

$${Δθ}^{′} = 2 π {f}^{′} ( \frac{L}{{v}_{2}} - \frac{L}{{v}_{1}} ) + ( {φ}_{2}^{′} - {φ}_{1}^{′} ) \qquad ( Equation 13 )$$

A relationship between the displacement L of the moving unit 120 and the phase difference Δθ′ according to the embodiment is illustrated by a graph different from the graph of FIG. 3 in the first embodiment because the frequency of the second alternating current signal source 501 is different.

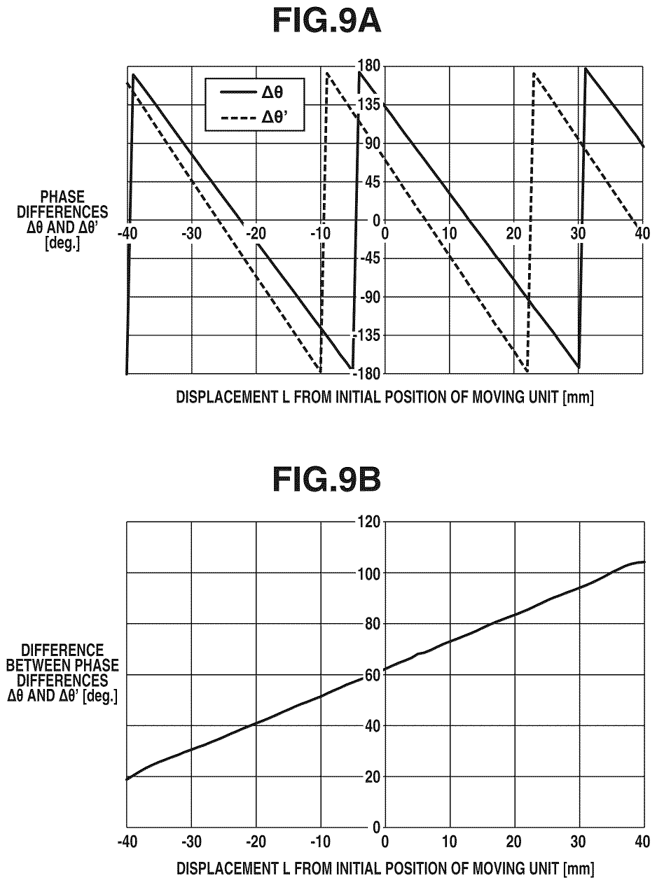

Each of FIGS. 9A and 9B illustrates a relationship between the displacement L of the transmission line coupler according to the embodiment and the phase differences Δθ and Δθ′.

Similar to the first embodiment, the frequency f of the signal output from the first alternating current signal source 101 is set to 10 GHz, and the phase difference φ₂−φ₁ output from the first phase difference detection unit 109 at the initial position L=0 mm is set to 133.2 degrees. The propagation speed v₁ is set to 1.62×10′ m/s, and the propagation speed v₂ is set to 3.00×10⁸ m/s. The frequency f′ of the signal output from the second alternating current signal source 501 is set to 11 GHz, and the phase difference φ₂′−φ₁′ output from the second phase difference detection unit 508 at the initial position L=0 mm is set to 71.0 degrees.

In FIG. 9A, the horizontal axis represents a displacement L from the initial position L=0 mm of the moving unit 120, and the vertical axis represents a phase difference Δθ output from the first phase difference detection unit 109 and a phase difference Δθ′ output from the second phase difference detection unit 508. The phase difference Δθ output from the first phase difference detection unit 109 and the phase difference Δθ′ output from the second phase difference detection unit 508 are different because the frequency f of the first alternating current signal source 101 and the frequency f of the second alternating current signal source 501 are different. In FIG. 9B, the horizontal axis represents a displacement L from the initial position L=0 mm of the moving unit 120, and the vertical axis represents a difference between the phase differences Δθ and Δθ′ output from the first and second phase difference detection units 109 and 508. From FIG. 9B, it can be seen that, with respect to the displacement L of the moving unit 120, the difference between the phase differences Δθ and Δθ′ output from the first and second phase difference detection units 109 and 508 becomes an eigenvalue. Therefore, the position of the moving unit 120 is uniquely determined from the difference between two phase differences Δθ and Δθ′. In other words, the absolute position of the moving unit 120 can be acquired by detecting phase differences using two frequencies, without using the counting unit 110.

As described above, according to the embodiment, the absolute position of the moving unit 120 can be calculated from a difference between the values output from the first and second phase difference detection units 109 and 508. In the embodiment, the two frequencies f and f are separated by the band-pass filters 505 and 507. However, the frequencies may alternatively be separated by the wavelength of light propagated through the transmission unit 106, the propagation path 107, and the reception unit 108, without using the band-pass filters 505 and 507, and then transmitted to the first and second phase difference detection units 109 and 508. Similar to the first embodiment, as long as the propagation speed in the first transmission line coupler 104 and the propagation speed in the propagation path 107 are different from each other, the transmission unit 106, the propagation path 107, and the reception unit 108 may use a radio wave, a sound wave, or the other methods. Further, a cable, a fiber, a waveguide, a transmission line coupler made of a different base material, a slip ring, or the other transmission line can be used. Similarly, a cable, a fiber, a waveguide, a slip ring, or other components can also be used for the first transmission line coupler 104 and the first coupler 105 as long as the propagation time is different from the propagation time in the propagation path 107.

The first and second alternating current signal sources 101 and 501 may be implemented as one frequency variable alternating current signal source, and the first and second phase difference detection units 109 and 508 may be implemented as one phase difference detection unit. Then, signals may be propagated to the first and second phase difference detection units 109 and 508 in a time division manner. In this case, the band-pass filters 504, 505, 506, and 507 are not used.

### Fifth Embodiment

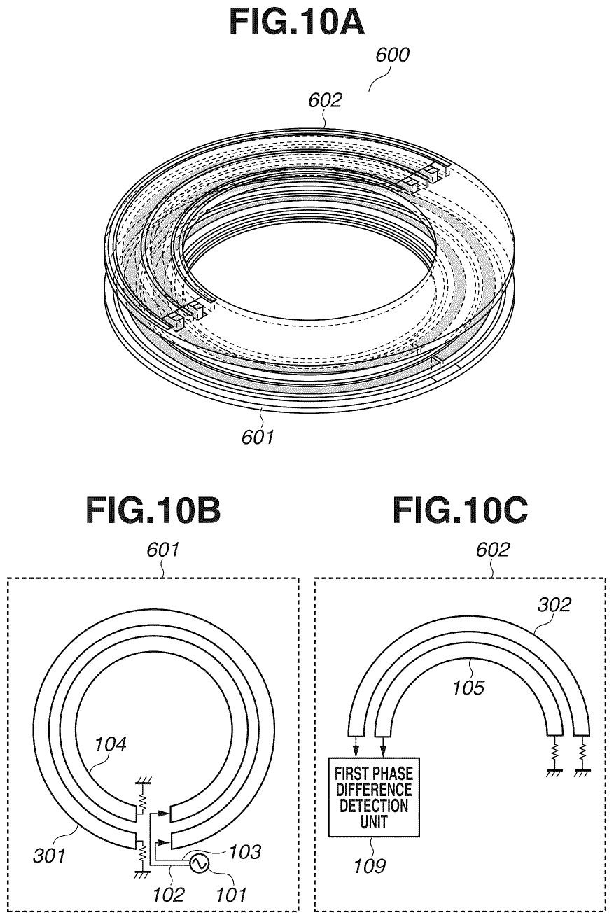

FIGS. 10A, 10B, and 10C are diagrams illustrating configurations of a displacement measurement system according to the embodiment. More specifically, FIG. 10A illustrates a displacement measurement system 600 which includes a fixed part 601 and a rotation part 602. FIG. 10B illustrates the fixed part 601 which includes the first alternating current signal source 101, the first cable 102, the second cable 103, the first transmission line coupler 104, and the second transmission line coupler 301.

The first and second transmission line couplers 104 and 301 are formed in concentric circular shapes having different radii, and one end portions of the first and second transmission line couplers 104 and 301 are connected to the first alternating current signal source 101 via the first cable 102 and the second cable 103, respectively, whereas the other end portions of the first and second transmission line couplers 104 and 301 are terminated with resistors.

FIG. 10C illustrates the rotation part 602 which includes the first coupler 105, the second coupler 302, and the first phase difference detection unit 109. The first and second couplers 105 and 302 are formed in concentric arc-like shapes having different diameters, and one end portions of the first and second couplers 105 and 302 are connected to the first phase difference detection unit 109, whereas the other end portions of the first and second couplers 105 and 302 are terminated with resistors. The rotation part 602 can rotate about the center of the circular-shape fixed part 601 as a rotation axis. The first and second couplers 105 and 302 are formed into concentric arc-like shapes having radii identical to the radii of the first and second transmission line couplers 104 and 301 illustrated in FIG. 10B. With this configuration, the first coupler 105 can revolve along the first transmission line coupler 104, and the second coupler 302 can revolve along the second transmission line coupler 301, while maintaining a certain distance. The signal from the first alternating current signal source 101 input to the first transmission line coupler 104 propagates to the first coupler 105 via electromagnetic coupling. Similarly, the signal from the second alternating current signal source 501 input to the second transmission line coupler 301 propagates to the second coupler 302 via electromagnetic coupling.

In the above-described configuration, the displacement measurement system according to the embodiment can detect the displacement of the rotation angle of the rotation part 602 from the phase difference output from the first phase difference detection unit 109.

Because the radii of the first and second transmission line couplers 104 and 301 are different, the amounts of change in the propagation distances of the first and second transmission line couplers 104 and 301 with respect to the displacement of the rotation angle are different from each other. As a result, a phase difference occurs, and the displacement of the rotation angle can be acquired.

A method for measuring a displacement by detecting a phase difference according to the embodiment will be described. The amount of phase change, which occurs when a signal propagates from the first alternating current signal source 101 to the first phase difference detection unit 109 via the first cable 102, the first transmission line coupler 104, and the first coupler 105, in a state where the rotation part 602 is located at the initial position, is denoted by φ₁. The amount of phase change, which occurs when a signal propagates from the first alternating current signal source 101 to the first phase difference detection unit 109 via the second cable 103, the second transmission line coupler 301, and the second coupler 302, in a state where the rotation part 602 is located at the initial position, is denoted by φ₂. The frequency of the signal output from the first alternating current signal source 101 is denoted by f, the propagation speed when the signal from the first alternating current signal source 101 propagates through the first transmission line coupler 104 and the second transmission line coupler 301 is denoted by v₁.

The amount of displacement of the rotation angle from the initial position of the rotation part 602 is denoted by a, the radius of the first transmission line coupler 104 is denoted by r₁, and the radius of the second transmission line coupler 301 is denoted by r₂. The amount of phase change 01, which occurs when a signal propagates from the first alternating current signal source 101 to the first phase difference detection unit 109 via the first cable 102, the first transmission line coupler 104, and the first coupler 105, in a state where the rotation part 602 is displaced from the initial position by the amount of displacement a of the rotation angle is expressed by the following equation.

$${θ}_{1} = 2 π f \frac{α {r}_{1}}{{v}_{1}} + {φ}_{1} \qquad ( Equation 14 )$$

Similarly, the amount of phase change θ₂, which occurs when a signal propagates from the first alternating current signal source 101 to the first phase difference detection unit 109 via the second cable 103, the second transmission line coupler 301, and the second coupler 302 is expressed by the following equation.

$${θ}_{2} = 2 π f \frac{α {r}_{2}}{{v}_{1}} + {φ}_{2} \qquad ( Equation 15 )$$

Accordingly, the phase difference Δθ output from the first phase difference detection unit 109 is expressed by the following equation.

$$Δθ = {θ}_{2} - {θ}_{1} = 2 π f ( \frac{α {r}_{2}}{{v}_{2}} - \frac{α {r}_{1}}{{v}_{1}} ) + ( {φ}_{2} - {φ}_{1} ) \qquad ( Equation 16 )$$

As described above, due to the radii of the first and second transmission line couplers 104 and 301 being different from each other, the amount of displacement α of the rotation angle can be acquired from the phase difference Δθ detected by the first phase difference detection unit 109. Therefore, it is possible to measure a displacement angle by detecting a phase difference.

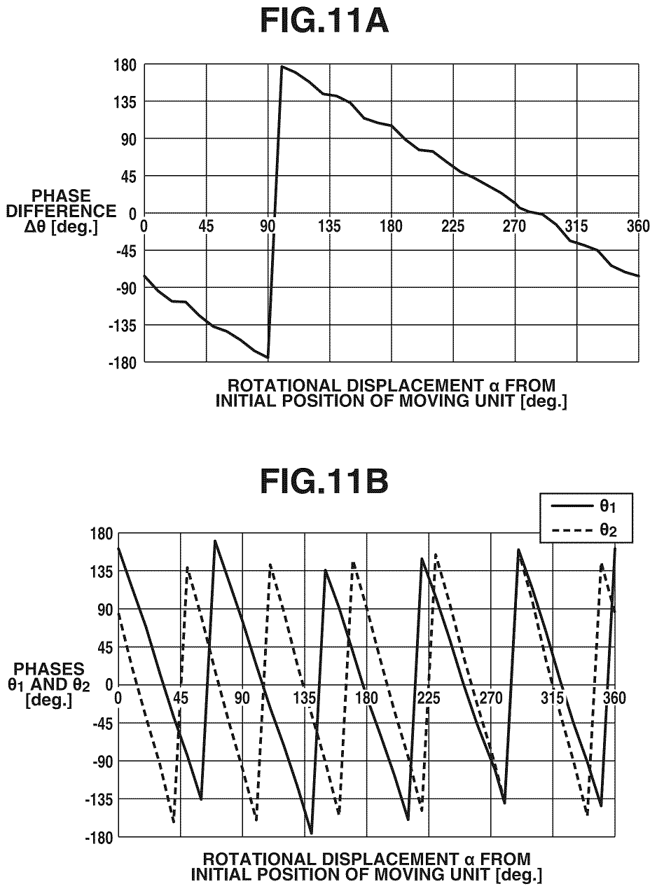

FIG. 11A illustrates a relationship between the rotational displacement α of the rotation part 602 and the phase difference Δθ according to the embodiment. The horizontal axis represents the rotational displacement α with respect to the initial position α=0 degrees of the rotation part 602, and the vertical axis represents the phase difference Δθ output from the first phase difference detection unit 109. The frequency f of the signal output from the first alternating current signal source 101 is set to 8.6 GHz, and the phase difference φ₂−φ₁ at the initial position α=0 degrees is set to −76.3 degrees. The first transmission line coupler 104 is made of a glass epoxy substrate (FR4), and the propagation speed v₁ is set to 1.68×10⁸ m/s. The radius of the first transmission line coupler 104 is set to 16.25 mm, and the radius of the second transmission line coupler 301 is set to 19.35 mm.

The propagation distance with respect to the rotational displacement α becomes different between the case where a signal from the first alternating current signal source 101 propagates through the first transmission line coupler 104 and the case where the signal propagates through the second transmission line coupler 301. Therefore, as illustrated in FIG. 11A, the phase difference Δθ changes depending on the rotational displacement α as expressed by the equation 14. Accordingly, the rotational displacement a of the rotation part 602 can be acquired by measuring a phase difference Δθ with the first phase difference detection unit 109.

In a case where the length of the transmission line of each of the first and second transmission line couplers 104 and 301 is a natural number multiple of the wavelength at the frequency of the first alternating current signal source 101, the value of the phase difference Δθ becomes equal when the rotational displacement α is 0 degrees and when it is 360 degrees. In a case where the length of the transmission line of the first transmission line coupler 104 is a natural number multiple of the wavelength, the amount of phase change of the signal from the first alternating current signal source 101 becomes equal between the one end portion of the first transmission line coupler 104 connected to the first cable 102 and the other end portion thereof terminated with a resistor. Therefore, when the rotational displacement α increases from 0 degrees and reaches 360 degrees, the phase of the signal input to the first phase difference detection unit 109 from the first coupler 105 becomes equal to the phase when the rotational displacement α is 0 degrees. Similarly, in a case where the length of the transmission line of the second transmission line coupler 301 is a natural number multiple of the wavelength, the amount of phase change of the signal from the first alternating current signal source 101 becomes equal between the one end portion of the second transmission line coupler 301 connected to the second cable 103 and the other end portion thereof terminated with a resistor. Therefore, when the rotational displacement α increases from 0 degrees and reaches 360 degrees, the phase of the signal input to the first phase difference detection unit 109 from the second coupler 302 becomes equal to the phase when the rotational displacement α is 0 degrees.

As a result, the value of the phase difference Δθ becomes equal when the rotational displacement α is 0 degrees and when it is 360 degrees. FIG. 11A illustrates a relationship between the rotational displacement α of the rotation part 602 and the phase differences Δθ and Δθ′. The length of the transmission line and the frequency of the signal from the first alternating current signal source 101 are adjusted such that the phase 01 of the signal propagated through the first transmission line coupler 104, which is shorter, corresponds to five wavelengths per revolution, and the phase of the signal propagated through the second transmission line coupler 301, which is longer, corresponds to six wavelengths per revolution. Therefore, for both of the phases θ₁ and θ₂, the value of the phase difference Δθ becomes equal when the rotational displacement α is 0 degrees and when it is 360 degrees. The phase difference can be detected stably and accurately, in comparison to the case where the value of the phase difference Δθ becomes different when the rotational displacement α is 0 degrees and when it is 360 degrees, due to the absence of a jump in the value of the phase difference detection unit 109 near 0 degrees. Therefore, it is possible to accurately acquire the rotational displacement α.

Furthermore, since the difference between the lengths of the transmission lines of the first and second transmission line couplers 104 and 301 is one wavelength, the phase difference Δθ with respect to the rotational displacement α, as illustrated in FIG. 11A, is uniquely determined. Therefore, the absolute position of the rotation angle of the rotation part 602 can be calculated without using the counting unit 110.

As described above, according to the embodiment, the rotation angle of the rotation part 602 can be calculated from the value output from the first phase difference detection unit 109. Similar to the third embodiment, in the embodiment, data transmission may be executed simultaneously. It is possible to execute non-contact data transmission over two channels from the first transmission line coupler 104 to the first coupler 105, and from the second transmission line coupler 301 to the second coupler 302. The two channels may consist of two single-ended transmission channels or a pair of differential transmission channels. The data transmission direction may be reversed. In other words, data can be transmitted from the first coupler 105 to the first transmission line coupler 104, and from the second coupler 302 to the second transmission line coupler 301. Alternatively, in one embodiment, only one direction may be reversed to enable bidirectional data transmission. The number of data transmission channels can be increased by arranging the channels in a concentric state. Although termination resistors are connected to the first and second couplers 105 and 302, the termination resistors may be omitted in a case where the frequency of the signal of the first alternating current signal source 101 and the data transmission rate are low. In this case, for example, each of the first coupler 105 and the second coupler 302 may be connected to the first phase difference detection unit 109 at a central portion instead of the end portion.

### Sixth Embodiment

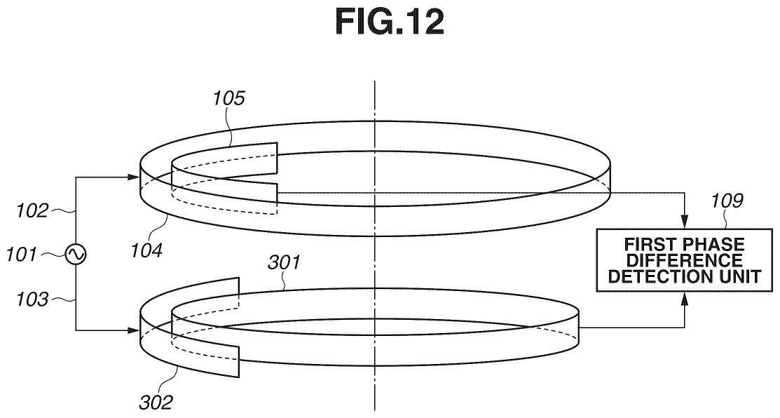

FIG. 12 is a diagram illustrating a configuration of a displacement measurement system according to the embodiment. Although the displacement measurement system according to the embodiment also includes a rotation part similar to the fifth embodiment, the rotation part is arranged in a concentric cylindrical state. The first transmission line coupler 104 and the second coupler 302 are arranged on the fixed side, and on the inner sides of the first transmission line coupler 104 and the second coupler 302, the first coupler 105 and the second transmission line coupler 301 are respectively arranged on the rotation side. All of these four elements are arranged in a concentric state, and the first coupler 105 and the second transmission line coupler 301 arranged on the rotation side rotate about the same axis. Since the first transmission line coupler 104 is positioned on the outer fixed side and the second transmission line coupler 301 is positioned on the inner rotation side, the radii of the concentric circles at the respective positions where the first transmission line coupler 104 and the second transmission line coupler 301 are arranged are different.

The signal from the first alternating current signal source 101 is input to the first transmission line coupler 104 via the first cable 102. The first coupler 105 can revolve while maintaining a certain distance from the first transmission line coupler 104. The signal from the first alternating current signal source 101 input to the first transmission line coupler 104 is propagated to the first coupler 105 via electromagnetic field coupling, and then is input to the first phase difference detection unit 109. The first transmission line coupler 104 includes end portions (not illustrated), and one end portion is connected to the first cable 102, whereas the other end portion is terminated with a resistor. The first transmission line coupler 104 may be divided into a plurality of elements arranged in the circumferential direction.

In this case, the first cable 102 is connected to one end portion of each of the elements, and the signal from the first alternating current signal source 101 is input to all of the elements. The other end portion of each of the elements constituting the first transmission line coupler 104 is terminated with a resistor. With the above-described configuration, at any optional rotation angle of the first coupler 105, the signal of the first alternating current signal source 101 propagates to the first coupler 105 from the first transmission line coupler 104, and is input to the first phase difference detection unit 109.

The signal from the first alternating current signal source 101 is input to the second coupler 302 via the second cable 103. The second transmission line coupler 301 can revolve while maintaining a certain distance from the second coupler 302. The signal from the first alternating current signal source 101 input to the second coupler 302 propagates to the second transmission line coupler 301 via electromagnetic coupling, and is input to the first phase difference detection unit 109. The second transmission line coupler 301 includes end portions (not illustrated), and one end portion is connected to the first phase difference detection unit 109, whereas the other end portion is terminated with a resistor. The second transmission line coupler 301 may be divided into a plurality of elements arranged in the circumferential direction. In this case, the first phase difference detection unit 109 is connected to one end portion of each of the elements, and regardless of which element of the second transmission line coupler 301 the signal from the first alternating current signal source 101 propagates to from the second coupler 302, it is input to the first phase difference detection unit 109. The other end portion of each of the elements constituting the second transmission line coupler 301 is terminated with a resistor. With the above-described configuration, at any optional rotation angle of the second transmission line coupler 301, the signal from the first alternating current signal source 101 propagates to the second transmission line coupler 301 from the second coupler 302, and is input to the first phase difference detection unit 109.

In the above-described configuration, the displacement measurement system according to the embodiment can detect the displacement of the rotation angle of the first coupler 105 and the second transmission line coupler 301, which are arranged on the rotation side, based on the phase difference output from the first phase difference detection unit 109. Since the radii of the first and second transmission line couplers 104 and 301 are different, the amounts of change of the propagation distances at the first and second transmission line couplers 104 and 301 with respect to the displacement of the rotation angle are different from each other. As a result, a phase difference occurs, and the displacement of the rotation angle can be acquired.

A method for measuring a displacement by detecting a phase difference according to the embodiment will be described. The amount of phase change, which occurs when a signal propagates from the first alternating current signal source 101 to the first phase difference detection unit 109 via the first cable 102, the first transmission line coupler 104, and the first coupler 105, in a state where the rotation side is located at the initial position, is denoted by φ₁. The amount of phase change, which occurs when a signal propagates from the first alternating current signal source 101 to the first phase difference detection unit 109 via the second cable 103, the second coupler 302, and the second transmission line coupler 301, in a state where the rotation side is located at the initial position, is denoted by φ₂. The frequency of the signal output from the first alternating current signal source 101 is denoted by f, the propagation speed when the signal from the first alternating current signal source 101 propagates through the first transmission line coupler 104 and the second transmission line coupler 301 is denoted by v₁.

The amount of displacement of the rotation angle from the initial position of the rotation side is denoted by a, the radius of the first transmission line coupler 104 is denoted by r₁, and the radius of the second transmission line coupler 301 is denoted by r₂. In a case where the rotation side is displaced from the initial position by the amount of displacement α of the rotation angle, the amount of phase change 01, which occurs when a signal propagates from the first alternating current signal source 101 to the first phase difference detection unit 109, is expressed by the equation 14. This signal propagates via the first cable 102, the first transmission line coupler 104, and the first coupler 105.

Similarly, the amount of phase change θ₂, which occurs when a signal propagates from the first alternating current signal source 101 to the first phase difference detection unit 109 via the second cable 103, the second coupler 302, and the second transmission line coupler 301, is expressed by the equation 15. As described above, a phase difference Δθ output from the first phase difference detection unit 109 is expressed by the equation 16, as in the fifth embodiment. As described above, Due to the radii of the first and second transmission line couplers 104 and 301 being different from each other, the amount of displacement α of the rotation angle can be acquired from the phase difference Δθ detected by the first phase difference detection unit 109. Therefore, it is possible to measure a displacement by detecting a phase difference.

According to the embodiment, the rotation angles of the first coupler 105 and the second transmission line coupler 301 arranged on the rotation side can be calculated from a value output from the first phase difference detection unit 109. Similar to the third and the fifth embodiments, in the embodiment, data transmission may be executed simultaneously. It is possible to execute non-contact bidirectional data transmission between the fixed side and the rotation side, i.e., transmission of data from the first transmission line coupler 104 as the fixed side to the first coupler 105 as the rotation side, and transmission of data from the second transmission line coupler 301 as the rotation side to the second coupler 302 as the fixed side. The data transmission direction may be reversed. In other words, data can be transmitted from the first coupler 105 to the first transmission line coupler 104, and from the second coupler 302 to the second transmission line coupler 301. Alternatively, in one embodiment, only one of the data transmission directions may be reversed. The number of data transmission channels can be increased by arranging the channels on the cylindrical axis.

The first coupler 105 may be connected to the first phase difference detection unit 109 at the end portion, or at the central portion. The second coupler 302 may be connected to the second cable 103 at the end portion, or at the central portion. A termination resistor may be connected to the end portion of each of the first and second couplers 105 and 302.

The first alternating current signal source 101 may be arranged on the rotation side and connected to the first coupler 105 and the second transmission line coupler 301. In this case, the first phase difference detection unit 109 may be arranged on the fixed side and connected to the first transmission line coupler 104 and the second coupler 302.

According to the disclosure, it is possible to provide a system in which the detection accuracy can be kept constant regardless of the position of a detection device on a transmission line.

### OTHER EMBODIMENTS

Embodiment(s) of the disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the disclosure has been described with reference to embodiments, it is to be understood that the disclosure is not limited to the disclosed embodiments. The scope of the following claims is to be accorded the broadest interpretation so as to encompass all such modifications and equivalent structures and functions.

This application claims the benefit of Japanese Patent Application No. 2024-195709, filed Nov. 8, 2024, which is hereby incorporated by reference herein in its entirety.

What is claimed is:

1. A system comprising:
a first coupler having one end portion terminated and configured to receive a first signal input from another end portion;
a second coupler configured to move in a direction in which the first coupler extends while maintaining a certain distance from the first coupler;
a transmission unit configured to receive a second signal having a frequency same as a frequency of the first signal and transmit a signal;
a reception unit configured to receive the signal output from the transmission unit;
a detection unit configured to detect a phase difference between a signal output from the second coupler via the first coupler based on the first signal and a signal output from the reception unit via the transmission unit based on the second signal; and
a calculation unit configured to calculate a position based on information of the phase difference output from the detection unit.

2. The system according to claim 1, further comprising a counting unit configured to change a value of a counter every time the phase difference exceeds 180 degrees.

3. The system according to claim 2, wherein the calculation unit calculates a position of the second coupler relative to the first coupler based on the phase difference and the value of the counter output from the counting unit.

4. The system according to claim 1, wherein the detection unit outputs the phase difference by quadrature-demodulating two signals, including the signal output from the second coupler and the signal output from the reception unit, and converting the two signals into polar coordinates.

5. The system according to claim 2, wherein, in a case where the second coupler moves in a direction of the end portion of the first coupler from which a signal is input, and the phase difference becomes 180 degrees, the counting unit decrements the value of the counter by one.

6. The system according to claim 2, wherein, in a case where the second coupler moves in a direction of the end portion of the first coupler at which a termination resistor is disposed, and the phase difference becomes 180 degrees, the counting unit increments the value of the counter by one.

7. The system according to claim 1,
wherein the transmission unit includes an emitting element,
wherein the reception unit includes a receiving element, and
wherein the second signal is input to the detection unit via optical coupling.

8. A system comprising:
a first coupler having one end portion terminated and configured to receive a first signal input from another end portion;
a second coupler configured to move in a direction in which the first coupler extends while maintaining a certain distance from the first coupler;
a third coupler having one end portion terminated and configured to receive a second signal input from another end portion;
a fourth coupler configured to move in a direction in which the third coupler extends while maintaining a certain distance from the third coupler;
a detection unit configured to detect a phase difference between a signal output from the second coupler via the first coupler based on the first signal and a signal output from the fourth coupler via the third coupler based on the second signal; and
a calculation unit configured to calculate a position based on information of the phase difference output from the detection unit.

9. The system according to claim 8,
wherein the first coupler is formed on a first substrate, and the third coupler is formed on a second substrate, and
wherein a dielectric constant of the first substrate is different form a dielectric constant of the second substrate.

10. The system according to claim 8, further comprising a counting unit configured to change a value of a counter every time the phase difference exceeds 180 degrees.

11. The system according to claim 10, wherein the calculation unit calculates a position of the second coupler relative to the first coupler based on the phase difference and the value of the counter output from the counting unit.

12. A method of a system,
the system including:
a first coupler having one end portion terminated and configured to receive a first signal input from another end portion;
and a second coupler configured to move in a direction in which the first coupler extends while maintaining a certain distance from the first coupler,
the method comprising:
receiving a second signal having a frequency same as a frequency of the first signal and transmitting a signal;
receiving the transmitted signal;
detecting a phase difference between a signal output from the second coupler and the signal received and output by the receiving; and
calculating a position based on information of the detected phase difference.

13. The method according to claim 12, further comprising changing a value of a counter every time the phase difference exceeds 180 degrees.

14. The method according to claim 13, further comprising calculating a position of the second coupler relative to the first coupler based on the phase difference and the value of the counter.

15. The method according to claim 12, wherein the detecting outputs the phase difference by quadrature-demodulating two signals, including the signal output from the second coupler and the signal output from the receiving, and converting the two signals into polar coordinates.

16. The method according to claim 13, wherein, in a case where the second coupler moves in a direction of the end portion of the first coupler from which a signal is input, and the phase difference becomes 180 degrees, the changing decrements the value of the counter by one.

17. The method according to claim 13, wherein, in a case where the second coupler moves in a direction of the end portion of the first coupler at which a termination resistor is disposed, and the phase difference becomes 180 degrees, the changing increments the value of the counter by one.
